(19) United States
(12) Patent Application Publication
(10) Pub. No.: US 2024/0019498 A1
(43) Pub. Date: Jan. 18, 2024

(54) Method and Apparatus for Detecting a Self-Discharge Fault of a Device Battery, as well as Determining a Criticality of a Detected Self-Discharge Fault

(71) Applicant: Robert Bosch GmbH, Stuttgart (DE)

(72) Inventors: Volker Doege, Dischingen (DE); Christian Simonis, Leonberg (DE); Mario Kluender, Renningen (DE)

(21) Appl. No.: 18/352,534

(22) Filed: Jul. 14, 2023

(30) Foreign Application Priority Data
Jul. 18, 2022 (DE) 10 2022 207 311.8

(51) Int. Cl. G01R 31/396

(52) U.S. Cl. CPC G01R 31/396; B60L 58/12

(57) ABSTRACT

A method for detecting a self-discharge fault of a device battery of a technical device and its criticality includes (a) providing at least one operating variable curve of at least one operating variable of the device battery, (b) determining at least one operational feature based on the at least one operating variable curve, (c) detecting a self-discharge fault based on fault criteria depending on the at least one operating feature, (d) determining a criticality of the self-discharge fault depending on which of the fault criteria are met, and (e) signaling a self-discharge fault depending on its criticality.

This application claims priority under 35 U.S.C. § 119 to application no. DE 10 2022 207 311.8, filed on Jul. 18, 2022 in Germany, the disclosure of which is incorporated herein by reference in its entirety.

The disclosure relates to diagnostic and monitoring methods for detecting functional and safety-critical events in electrochemical device batteries based on operating variable of the device battery.

### BACKGROUND

The self-discharge of an electrochemical device battery, for example a lithium ion battery, ranges from 0.5% to 2% per month at a state of charge above 50% and at room temperature in case of a proper battery. However, self-discharge rates for proper batteries will vary depending on the battery manufacturer and with respect to the components and materials used. A self-discharge of a battery can have various causes. These are differentiated by internal/external and physical/chemical short-circuit mechanisms.

Detecting an increase in self-discharge can be indicative of an imminent critical fault. This is particularly important, because some of the causes of self-discharge in continued operation can lead to an unwanted, amplifying thermal runaway of the battery, which can lead to the destruction and endangerment of facilities or individuals. Indications of imminent short-term capacity declines and malfunctions are also of great interest, for example, because they are relevant for operational safety.

### SUMMARY

According to the present disclosure, there is provided a method and apparatus for detecting a self-discharge fault of a device battery, as well as for determining a criticality of a detected self-discharge fault, as well as an apparatus concerning the same. Further configurations are specified below.

According to a first aspect, a method for detecting a self-discharge fault and its criticality is provided, with the following steps: (a) providing at least one operating variable curve of at least one operating variable, (b) determining at least one operational feature based on the at least one operating variable curve, (c) detecting a self-discharge fault based on fault criteria depending on the at least one operating feature, (d) determining a criticality of the self-discharge fault depending on which of the fault criteria are met, and (e) signaling a self-discharge fault depending on its criticality.

Although self-discharge is common to a small degree with electrochemical batteries, enhanced self-discharge events can indicate the presence of a fault. Such faults can initially be non-critical and may not significantly interfere with the operation of the battery, but can lead to critical battery conditions over a longer period of time, such that early detection of an abnormal battery state can help to avoid such critical battery conditions.

Generally, self-discharge faults can have various causes. For example, self-discharge faults can be differentiated according to cell-internal short-circuit mechanisms and cell-external short-circuit mechanisms, which can each be further differentiated into electrochemical and physical short-circuit mechanisms. Furthermore, these faults can be differentiated with regard to the amount of the short-circuit resistance that results from this and which also determines the criticality of the fault that has occurred.

A self-discharge fault of a battery can occur in a storage cell, module, or pack and can be determined as an electrical or electrochemical or chemical discharge process not caused by the removal of energy from the battery. Self-discharge is undesirable but cannot be completely avoided, even with a proper battery.

Internal self-discharge causes include a malfunction of the separator in the battery separating anode and cathode ranges from one another. Causes for this can include, for example, a lithium plating, which can lead to a short-circuit or a faulty heat generation by a chemical reaction with the electrolyte and thus causes self-discharge or a thermal runaway.

Furthermore, chemical secondary reactions with an active material in the battery, such as lithium, can lead to self-discharge effects, such as due to electrolyte oxidations on the cathode or deposited lithium on the anode side. Because the undesired secondary reactions do not have to occur simultaneously on the anode and cathode side, this effect can also lead to an unbalanced anode and cathode state, which reduces cell capacity and changes the OCV characteristic curve (idle voltage characteristic). In addition, unwanted secondary reactions can also lead to unwanted gassing in the cell, which increases the internal pressure of the cell.

Furthermore, the separator can be damaged by mechanical stress. Mechanical stress can also compromise the integrity of the electrode coating matrix, which can result in inhomogeneous power distribution and/or short-circuits with local temperature increases.

Furthermore, damage to conductive components can cause internal short-circuits between the electrodes or between an electrode and the storage cell housing or other internal current-conducting paths. For example, metal particles remaining in the battery cell from the production process or dendrites of lithium plating penetrating the electrode separator can result in short-circuits. Furthermore, a short-circuit can occur between electrodes or in the battery cell housing due to a production fault. In addition, chemical contaminations during production steps, such as moisture, can cause undesirable and stronger secondary reactions within the battery cell, which cause increased self-discharge.

External self-discharge causes relate to causes that lie outside the battery cells. These can relate, for example, to a reduction of the insulation resistance with respect to the electrical connection lines of the housing and the contacts of the cooling channels. These can cause high or low short-circuit currents, depending on the degree of the reduced short-circuit resistance. Common causes of insulation faults are degradation of the insulation material or objects that penetrate the insulation material. Furthermore, circuitry associated with the battery cells can in particular cause the battery management system to produce an increased current draw from the battery due to faults that are often not detectable by current sensors.

It can be provided that the at least one operating variable comprises at least one of the following variables: a cell voltage, a module voltage, a pack voltage of battery cells, battery modules, or a battery pack of multiple battery modules, a cell state of charge (SOC), a module state of charge, and a pack state of charge.

In particular, the at least one operating feature can comprise a statistical or aggregated variable of a temporal curve of one or more operating variable of the device battery, and in particular can comprise a deviation from a temporal average of the operating variable and/or a temporal change of the at least one operating variable.

Furthermore, at least one further operating feature can be provided, comprising one or more operating features: a balancing frequency, a balancing duration, a balancing energy throughput rate, a balancing charge throughput rate, respectively in relation to a specified evaluation period, a state of charge difference of the electrode-related states of charge, and a time gradient of the state of charge difference of the electrode-related states of charge.

According to one embodiment, the fault criteria can be defined in a rule-based manner, in particular as threshold values for the operating features and, if necessary, for the further operating features.

In particular, the thresholds can be determined depending on operating variable curves and, if necessary, further operational features of a plurality of device batteries.

According to the above method, operating features of a device operating on a device battery are detected as parameters of battery operation and evaluated against specified fault criteria. The assessment of the parameters is preferably carried out using threshold value comparisons, wherein the combination of the fulfilled fault criteria indicates a presence and a criticality of the self-discharge fault. The criticality is determined by the severity of the fault detected and the trend of the self-discharge development.

The thresholds result from the known behavior of the respective device battery in terms of its typical self-discharge rate. The typical self-discharge rate can vary depending on the manufacturer and technology used (differences also within Li-ion technology) and is also dependent on age, state of charge, and temperature, for example. At the system level, there are also self-discharge effects due to e.g. residual currents of semiconductor components and finite insulation values. A typical value for cell level self-discharge is in the range of 0.5 to 1% for SOC=80% for Li-ion cells.

The fault monitoring can be based on monitoring cell voltages and/or cell states of charge and/or their gradients and/or on monitoring the effort required for cell balancing and/or based on monitoring the state of charge deviation between an electrode-related state of charge of the positive electrode and an electrode-related state of charge of the negative electrode and/or their gradients. The variables of the electrode related state of charge result as electrochemical parameters from an electrochemical battery model that is performed continuously based on operating variable curves of the individual battery cells and can serve to determine electrochemical parameters.

Additionally, idling voltage characteristic curve changes can be determined based on the model and adjusted via continuous voltage monitoring for steady-state conditions. This allows the determination of states of charge relative to electrodes so that an electrode-related state of charge variation can be determined. The positive and negative open-circuit potential curve (ocv: open-circuit voltage characteristic curve) within a cell have characteristic patterns (voltage as a function of the lithium charge state). If only one electrode is discharged, the patterns shift against one another (even if only one electrode has a capacity loss) and this can be seen in the full cell OCV curve. This can then be obtained by means of a curve fitting with known or also estimated active material combinations.

The above monitoring criteria allow the identification and classification of increased self-discharge cases between critical and non-critical effects. The threshold values for the threshold value comparisons can be determined from data of a plurality of batteries of the same type, in particular in an external central processing unit, which evaluates operating variable curves of a plurality of batteries and in particular depends on the current state of charge and the temperature of the battery to be tested. The self-discharge fault model can evaluate the corresponding self-discharge cases against the fulfilled or unfulfilled fault criteria and take appropriate action depending on what criticality of the self-discharge fault is determined. For example, an activation of a cooling device or signaling of a fault that has occurred can be performed by a user of the technical device.

In accordance with one embodiment, a critical self-discharge fault can be determined when an amount of time of a change in a state of charge exceeds a threshold.

According to a further aspect, an apparatus is provided for carrying out the above method.

### BRIEF DESCRIPTION OF THE DRAWINGS

Embodiments are explained in greater detail below with reference to the accompanying drawings. The figures show:

FIG. 1 which is a schematic view of a system comprising a fleet of battery-operated vehicles communicatively connected to a central processing unit; and

FIG. 2 which is a flowchart illustrating a method for detecting a self-discharge and carrying out a fault response.

### DETAILED DESCRIPTION

The method will now be described in greater detail, by way of example, using a vehicle battery in a vehicle as a technical device. The vehicle can be part of a fleet of vehicles having type-matched vehicle batteries and can be in communication with an external central processing unit in which a self-discharge fault algorithm is carried out.

The above example is representative of a multiplicity of stationary or mobile devices with a network-independent energy supply, such as vehicles (electric vehicles, pedelecs, etc.), systems, machine tools, household appliances, IOT devices, and the like, which are connected via a corresponding communication connection (e.g., LAN, Internet) to an external central unit (cloud).

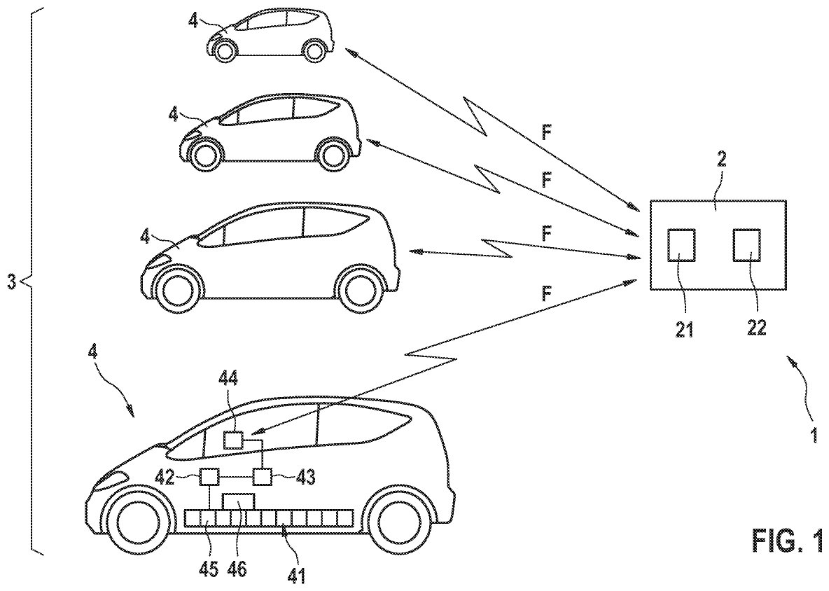

FIG. 1 shows a system 1 for collecting fleet data of a vehicle fleet in a central processing unit 2 for carrying out a monitoring method. The monitoring method serves to detect a self-discharge fault and to determine the criticality of the self-discharge fault of battery cells of the vehicle battery in a motor vehicle. FIG. 1 shows a vehicle fleet 3 with several motor vehicles 4.

One of the motor vehicles 4 is shown in greater detail in FIG. 1. The motor vehicles 4 each comprise a vehicle battery 41, an electric drive motor 42, and a control unit 43. The control unit 43 is connected to a communication system 44, which is suitable for transmitting data between the respective motor vehicle 4 and a central unit 2 (a so-called cloud).

The vehicle battery 43 comprises a plurality of battery cells 45. These are connected into modules and packs. Cells, modules, and/or packs can be monitored for self-discharge according to the method described below. The vehicle battery 41 is monitored and operated using a battery management system 46.

The battery management system 46 is in particular designed to provide operating variables for selected, selectable, or all battery cells 45 having a high temporal resolution, e.g., between 1 and 50 Hz, e.g. 10 Hz, and transmits such to the central unit 2 via the communication device 44. The operating variables F are detected as operating variable curves and can be transmitted regularly to the central unit 2 in uncompressed and/or compressed form. For example, by using compression algorithms, the time series can be transmitted to the central unit 2 in blocks at intervals of 10 min to several hours in order to minimize the data traffic to the central unit 2.

The operating variables F indicate at least variables describing the state of the battery cells 45. The operating variables F, in the case of a vehicle battery 41, can indicate an instantaneous cell current, an instantaneous cell voltage, an instantaneous cell state of charge (SOC) for each of the battery cells 45.

The central unit 2 comprises a data processing unit 21, in which the method described below can be performed, and a database 22 for storing data points, model parameters, states, and the like.

A monitoring method is implemented in the central processing unit 2, which receives the operating variable curves from the vehicles 4 and evaluates them for each vehicle 4 or each vehicle battery 41 in order to detect a possible self-discharge fault and assess its criticality.

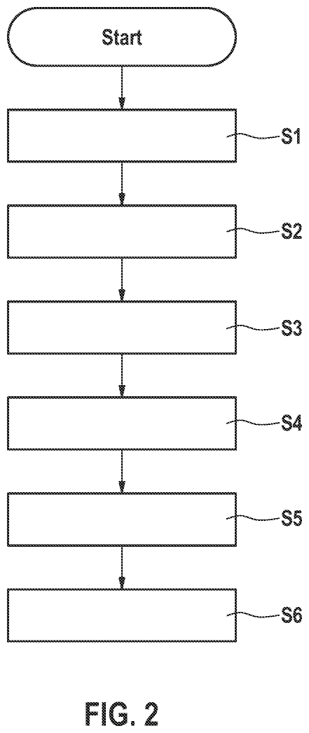

In the central processing unit 2, a method is carried out for detecting a self-discharge fault and determining a type of fault of a self-discharge fault that has occurred, as described below using the flowchart of FIG. 2. The method can be performed at specified evaluation times with historical operating variable curves for each of the battery cells 45 of the vehicle battery 41.

In step S1, operating variable data F indicative of historical operating variable curves is transmitted from the vehicles 4 of the vehicle fleet 3 to the external central processing unit 2. The operating variable curves can comprise cell voltages, module voltages, and pack voltages of battery cells, battery modules and a battery pack of multiple battery modules, as described above.

Furthermore, in step S2, information about a last balancing operation performed can be transmitted as operational features to the central processing unit 2, in particular the duration required for the balancing, an ampere hour throughput during the balancing, and/or a frequency with which balancing operations for the relevant vehicle battery have been performed over a previous specified period.

Furthermore, in step S3, battery conditions, such as temperature, state of charge, and state of aging that have been measured or determined in the battery management system of the respective vehicle battery can be transmitted to the external central processing unit 2.

From the above information, in step S4, further operating features are determined for each vehicle battery, which can include a cell-based cell voltage variation in terms of mean cell voltage (average across all battery cells) and a module voltage variation in terms of mean module voltage (average across all battery modules).

Furthermore, voltage change rates of the cell voltages, the module voltages, and the pack voltage can be determined with respect to time.

Alternatively or in addition to determining operating features from the voltages, corresponding operating features can also be determined based on the states of charge. The information regarding the states of charge can be determined in the battery management system 46 by evaluating the voltages, e.g. using a specified idling voltage characteristic curve.

Thus, for each vehicle battery, operational features can be determined that can include a cell-based cell charge variation in terms of a mean cell state of charge (average across all battery cells) and a module charge variation in terms of a mean module state of charge (average across all battery modules).

Furthermore, state of charge rates of change of the cell states of charge, the module states of charge, and the pack states of charge can be determined with respect to time.

These operating features are now monitored in step S5 of a rule-based self-discharge model with respect to specified fault criteria, which can be defined by, for example, thresholds. Monitoring is rule-based, so that a particular combination of fulfilled and unfulfilled fault criteria can indicate a particular criticality of a self-discharge fault or a development trend of the self-discharge fault.

Examples of fault criterion include:
the self-discharge is greater than a specified threshold, such as >2% SOC/month
a difference of the self-discharge rates of individual parallel connection planes of cells or of modules is greater than a specified threshold, such as e.g. 20%;
a module level balancing operation is triggered more frequently than 2× per month at specified SOH, e.g. 95%.

For the threshold-based rules, the measure of deviation from the known typical value can indicate criticality. The criticality can, but need not be, a linear function of the monitored variable.

The specification of the threshold values can take place in the form of look-up tables or also calculation functions (when processing operating parameters/states such as T, SOC, SOH, . . . ).

If at least one self-discharge fault is detected, then the criticality of the self-discharge fault can be signaled to a user of the vehicle in step S6.

If a critical fault is detected, further action can be taken. For example, a derating, i.e. a limitation of the performance of the vehicle battery 41, or an activation of a cooling device, can be carried out. Furthermore, a workshop stay could also be indicated or advised. Furthermore, if the criticality is high, the operation of the vehicle could also be completely blocked.

The thresholds for the fault criteria considered can also be derived from fleet data with particular relevance. In particular, after occurrence of a critical self-discharge fault, the values of the corresponding fault features can be determined at the time of occurrence of the first indication of the self-discharge fault, and the threshold values for the individual fault criteria can be extracted therefrom. The thresholds can be determined from pre-measurement series, or can also be determined from fleet operation, or can also be determined from a combination thereof.

What is claimed is:

1. A method for detecting a self-discharge fault of a device battery of a technical device and its criticality, comprising:
providing at least one operating variable curve of at least one operating variable of the device battery;
determining at least one operational feature based on the at least one operating variable curve;
detecting a self-discharge fault based on fault criteria depending on the at least one operating feature;
determining a criticality of the self-discharge fault depending on which of the fault criteria are met; and
signaling a self-discharge fault depending on its criticality.

2. The method according to claim 1, wherein the at least one operating variable comprises at least one of the following variables: a cell voltage, a module voltage, a pack voltage of battery cells, battery modules, or a battery pack of multiple battery modules, a cell state of charge, a module state of charge, and a pack state of charge.

3. The method according to claim 1, wherein the at least one operational feature comprises a deviation from a temporal average of the operating variable and/or a temporal change of the at least one operating variable.

4. The method according to claim 1, wherein at least one further operating feature is provided, comprising one or more operating features: a balancing frequency, a balancing duration, a balancing charge throughput rate, respectively in relation to a specified evaluation period, a state of charge difference of the electrode-related states of charge, and a time gradient of the state of charge difference of the electrode-related states of charge.

5. The method according to claim 1, wherein the fault criteria are provided in a rule-based manner.

6. The method according to claim 5, wherein the thresholds are determined depending on operating variable curves and, if necessary, further operational features of a plurality of device batteries.

7. The method according to claim 1, wherein the signaling of the self-discharge fault comprises and/or causes a derating depending on its criticality, and/or an activation of a cooling device comprises or causes an output of a warning and/or a partial or total blocking of the operation of the device.

8. The method according to claim 1, wherein a critical self-discharge fault is found when:
an amount of time of a change of a state of charge exceeds a threshold value, and/or
the self-discharge is greater than a specified threshold, and/or
the self-discharge rates of individual parallel connection planes of cells or of modules differ by a value greater than a specified threshold, and/or
a module plane balancing operation is performed at a frequency that is greater than a specified frequency.

9. An apparatus for carrying out the method according to claim 1.

10. A computer program product comprising commands which, when the program is executed by at least one data processing device, cause the latter to carry out the steps of the method according to claim 1.

11. A machine-readable storage medium comprising commands which, when executed by at least one data processing device, cause the latter to carry out the steps of the method according to claim 1.

12. The method according to claim 1, wherein the fault criteria are provided in a rule-based manner as threshold values for the operating features.

13. The method according to claim 1, wherein the fault criteria are provided in a rule-based manner as threshold values for the operating features and for the further operating features.
